(19) United States
(12) Patent Application Publication
(10) Pub. No.: US 2004/0023420 A1
(43) Pub. Date: Feb. 5, 2004

(54) Method for reduced photoresist usage

(75) Inventors: Hsin-Hung Chien, Hsinchu (TW); Chung-Jen Chu, Hsinchu (TW)

Correspondence Address: Finnegan, Henderson, Farabow,, Garrett & Dunner, L.L.P., 1300 I Street, N.W., Washington, DC, 20005-3315, US

(73) Assignee: Macromix International Co., Ltd.

(21) Appl. No.: 10/210,032

(22) Filed: Aug. 2, 2002

(51) Int. Cl. H01L 21/00

(52) U.S. Cl. 438/10; 438/17; 438/782

(57) ABSTRACT

A method for controlling photoresist dispensation that includes providing a coater having a spin module, providing a wafer, securing the wafer to the spin module, identifying a control board in the coater for controlling the spin module, identifying at least one node on the control board that provides a plurality of control signals to the spin module, providing a means for signal analysis, electrically connecting the means for signal analysis to the at least one node on the control board, dispensing an amount of photoresist on the wafer, identifying a first control signal that causes the spin module to provide a minimum spin velocity required to break a surface tension of the photoresist, measuring the first control signal, displaying the first control signal on the means for signal analysis, and controlling a duration of photoresist dispensation to provide a consistent photoresist thickness and to conserve photoresist usage.

### DESCRIPTION OF THE INVENTION

1. Field of the Invention

This invention relates in general to a semiconductor manufacturing process and, more particularly, to a method for reduced photoresist usage during photolithographic steps.

2. Background of the Invention

In the semiconductor manufacturing process, layers of semiconductor material with various patterns of circuit layouts are overlaid on top of one another at predetermined locations to form a plurality of integrated circuits (“ICs”) on a semiconductor wafer. A machine known as a “stepper” may be used at various stages of the manufacturing process to transfer circuit layout patterns onto a layer by exposing a photoresist to ultraviolet light through a mask, or reticle. The photoresist may be provided over a layer of semiconducting material, such as polysilicon, or a layer of dielectric material, such as oxide, by a rapidly spinning coating module, known as a “coater,” to dispense drops of photoresist. A coater holds the wafer with, for example, a vacuum chuck while a motor spins the wafer and chuck at a speed ranging from 0 to 6,000 rpm (revolution per minute). The photoresist is dispensed at the center of the wafer and is uniformly distributed to coat the wafer. After the photoresist is dry, the stepper places the reticle over the wafer to transfer the circuit layout patterns.

An important consideration in the manufacturing of semiconductor devices is cost, and the photoresist material is expensive. Therefore, it is advantageous to conserve the amount of photoresist dispensed during manufacturing, but to do so in a manner that does not adversely affect the process results. Another important consideration in the semiconductor manufacturing process is the consistent formation of a photoresist layer having the required thickness. Accordingly, the amount of photoresist dispensed by the coater must be consistent. Otherwise, inconsistent photoresist thickness may adversely affect the subsequent manufacturing process steps.

For example, conventional ultraviolet light sources with short wavelengths are normally used in a high-resolution photolithographic process. The depth of focus of a high-resolution photolithographic process is shallower than a relative low-resolution photolithographic process. Thus, a photoresist layer having a lower thickness is required. If, however, the photoresist layer provided by the coater is thicker or thinner than required, the subsequent lithographic process may be unable to reproduce the intended circuit layout patterns on the photoresist.

The conventional method for controlling the amount of photoresist dispensed on a wafer is by a human operator controlling the duration that a coater dispenses the photoresist by means of a stop-watch. This method is imprecise and inconsistent.

### SUMMARY OF THE INVENTION

In accordance with the invention, there is provided a method for controlling photoresist dispensation that includes providing a coater having a spin module, providing a wafer, securing the wafer to the spin module, identifying a control board in the coater for controlling the spin module, identifying at least one node on the control board that provides a plurality of control signals to the spin module, providing a means for signal analysis, electrically connecting the means for signal analysis to the at least one node on the control board, dispensing an amount of photoresist on the wafer, identifying a first control signal that causes the spin module to provide a minimum spin velocity required to break a surface tension of the photoresist, measuring the first control signal, displaying the first control signal on the means for signal analysis, and controlling a duration of photoresist dispensation to provide a consistent photoresist thickness and to conserve photoresist usage.

Also in accordance with the invention, there is provided a controlling photoresist dispensation that includes providing spin module, identifying a control board coupled to the spin module for controlling the spin module, identifying at least one node on the control board for providing a plurality of control signals to the spin module, providing an oscilloscope, electrically connecting the oscilloscope to the at least one node on the control board, measuring and displaying a first control signal on the oscilloscope that causes the spin module to provide a minimum spin velocity required to break a surface tension of the photoresist, and dispensing photoresist for a duration equal to a length of the first control signal.

It is to be understood that both the foregoing general description and the following detailed description are exemplary and explanatory only and are not restrictive of the invention, as claimed.

The accompanying drawing, which is incorporated in and constitutes a part of this specification, illustrates an embodiment of the invention and together with the description, serves to explain the principles of the invention.

### BRIEF DESCRIPTION OF THE DRAWINGS

FIG. 1 is a functional block diagram consistent with one embodiment of the method of the present invention.

### DESCRIPTION OF THE EMBODIMENTS

Reference will now be made in detail to the exemplary embodiments of the invention, an example of which is illustrated in the accompanying drawing. Wherever possible, the same reference numbers will be used throughout the drawings to refer to the same or like parts.

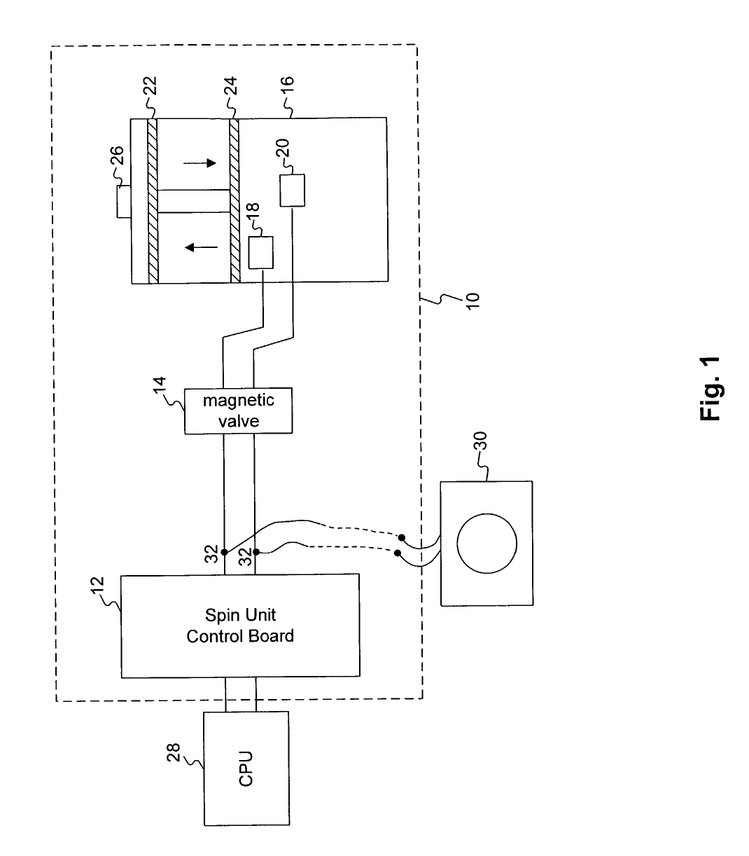

FIG. 1 is a functional block diagram consistent with one embodiment of the method of the present invention. Referring to FIG. 1, a photoresist spin coater 10 includes a spin unit control board 12, a magnetic valve 14 coupled to the spin unit control board 12, and a photoresist dispenser 16 coupled to the magnetic valve 14. The photoresist dispenser 16 includes an up valve 18, a down valve 20, an up sensor 22, a down sensor 24, and an output 26 to dispense the photoresist. The photoresist dispenser 16 also includes fluid lines (not shown), a spin module (not shown) and a wafer-handling module (not shown).

In operation, a computer-based control system 28 is coupled to the spin unit control board 12 of the coater 10 to control the operations of the coater 10. A wafer is secured by the wafer-handling module, for example, a vacuum chuck, and the spin module then spins the wafer at a high rate of speed. The up and down valves 18 and 20, respectively, together with the up sensor 22 and down sensor 24, control when the photoresist is dispensed through the output 26 and when the dispensation process ends. An amount of photoresist is dispensed through fluid lines and from the output 26 onto the spinning wafer. The photoresist evenly coats the wafer to form a layer of photoresist having a thickness.

In general, the layer thickness of a photoresist is determined by one of four physical properties, surface tension, specific gravity, solid content, and viscosity. Three of these properties, specific gravity, solid content and viscosity usually have already been determined in the photoresist material purchased from a vendor. The fourth physical property, surface tension, is the characteristic of liquids that pull surface molecules toward the body of liquid. In order to evenly distribute the photoresist material over the wafer surface, the spin unit of the coater 10 must provide enough centrifugal force to break the surface tension of the photoresist.

Referring again to FIG. 1, an oscilloscope 30 is provided to measure the control signals provided by the spin unit control board 12 to the spin module. The oscilloscope 30 may be substituted with any equipment that is capable of providing signal analysis. Accordingly, appropriate nodes for providing a control signal to the spin module are first identified. In this instance, nodes 32 of the spin unit control board 12 are identified as providing the appropriate control signals. Electrical connections are made between nodes 32 of the spin unit control board 12 and the oscilloscope 30 so that the control signals provided to the spin module may be observed and measured on the oscilloscope 30. Specifically, the oscilloscope 30 measures and displays the control signal that causes the spin module to provide the minimum spin velocity, measured in revolution per minute (rpm), required to break the surface tension of the photoresist so that the photoresist may be evenly distributed over the wafer surface. In one embodiment, this minimum spin velocity is identified, averaged over twenty-four wafers, at approximately 2,600 rpm.

Once the control signal for providing the minimum spin velocity is identified, the duration of photoresist dispensation by the coater 10 may be controlled to reduce the amount of photoresist usage during the manufacturing process. Generally, this signal should ideally be a step signal. The length, or duration, of the step signal represents the duration that the photoresist should be dispensed onto the wafer. However, there is a delay from the time that the up valve 18 is first activated until the spin module reaches the required spin velocity. Likewise, there is a delay from the time the down valve 20 is first triggered until the spin module drops below the spin velocity needed to break the surface tension of the photoresist. The step signal is therefore likely to appear on the oscilloscope in the shape of a trapezoid. Regardless, the duration of photoresist dispensation is still easily identifiable.

By identifying the minimum spin velocity required to break the surface tension of the photoresist, which varies among photoresist vendors, and by defining the duration that the photoresist is to be dispensed on a wafer, the method of the present invention is able to conserve the use of photoresist. At the same time, the method of the present invention provides for consistent and accurate dispensation of photoresist, and therefore consistent and accurate layer thickness of photoresist provided on a wafer surface.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for controlling photoresist dispensation, comprising:
providing a coater having a spin module;
providing a wafer;
securing the wafer to the spin module;
identifying a control board in the coater for controlling the spin module;
identifying at least one node on the control board that provides a plurality of control signals to the spin module;
providing a means for signal analysis;
electrically connecting the means for signal analysis to the at least one node on the control board;
dispensing an amount of photoresist on the wafer;
identifying a first control signal that causes the spin module to provide a minimum spin velocity required to break a surface tension of the photoresist;
measuring the first control signal;
displaying the first control signal on the means for signal analysis; and
controlling a duration of photoresist dispensation to provide a consistent photoresist thickness and to conserve photoresist usage.

2. The method as claimed in claim 1, wherein the duration is a length of the first control signal.

3. The method as claimed in claim 2, where the first control signal is substantially a step signal.

4. The method as claimed in claim 1, wherein the means for signal analysis is an oscilloscope.

5. A method for controlling photoresist dispensation, comprising:
providing spin module;
identifying a control board coupled to the spin module for controlling the spin module;
identifying at least one node on the control board for providing a plurality of control signals to the spin module;
providing an oscilloscope;
electrically connecting the oscilloscope to the at least one node on the control board;
measuring and displaying a first control signal on the oscilloscope that causes the spin module to provide a minimum spin velocity required to break a surface tension of the photoresist; and
dispensing photoresist for a duration equal to a length of the first control signal.

6. The method as claimed in claim 5, wherein the first control signal is substantially a step signal.

7. The method as claimed in claim 5, wherein the first control signal is trapezoid.
